(19) United States
(12) Patent Application Publication
(10) Pub. No.: US 2006/0231956 A1
(43) Pub. Date: Oct. 19, 2006

(54) Semiconductor device and method of manufacturing the same

(75) Inventors: Itaru Kawabata, Yokkaichi (JP); Hirofumi Inoue, Kamakura (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/402,919

(22) Filed: Apr. 13, 2006

(30) Foreign Application Priority Data
Apr. 13, 2005 (JP) 2005-115728

(51) Int. Cl. H01L 23/52

(52) U.S. Cl. 257/758

(57) ABSTRACT

A semiconductor device includes a first insulating film having a plurality of wiring trenches formed at predetermined intervals in an upper part, the first insulating film having an upper surface, a second insulating film formed on the upper surface of the first insulating film so as to be located between the wiring trenches, the second insulating film having an upper surface, a wiring layer buried in the wiring trenches and formed so that an upper surface thereof is located lower than an upper surface of the second insulating film, and a via plug formed so as to be connected to the upper surface of the wiring layer.

### CROSS-REFERENCE TO RELATED APPLICATIONS

This application is based upon and claims the benefit of priority from the prior Japanese Patent Application No. 2005-115728, filed on Apr. 13, 2005, the entire contents of which are incorporated herein by reference.

### BACKGROUND OF THE INVENTION

1. Field of the Invention

The present invention relates to a semiconductor device provided with via plugs each of which electrically connects two wiring layers to each other and a method of manufacturing the same.

2. Description of the Related Art

A damascene process is widely used when wiring and via plugs are formed in the manufacture of semiconductor devices. In the damascene process, a wiring material is buried in trenches or holes formed in an insulating film and thereafter flattened by a chemical mechanical polishing (CMP) process, whereby wiring or via holes are formed.

With recent high integration in semiconductor devices, a distance between one wiring and its nearby wiring has been reduced. However, since a suitable insulating performance needs to be maintained between the wires, it is difficult to reduce the distance between the wirings. Accordingly, processing at a high aspect ratio is required together with highly minute processing.

To overcome the foregoing problem, JP-A-2001-345380 discloses a technique for using as an interlayer insulating film an insulating film with a low relative permittivity, for example, 3.0 or below. According to the disclosed technique, an insulating film with a low relative permittivity is formed on a substrate formed with a wiring structure. Via holes are then formed in the insulating film with the low relative permittivity and wiring layers are formed in the respective via holes.

However, recent further high integration in semiconductor devices has reduced a distance between the neighboring wirings. As a result, when a mask pattern is displaced during the forming of via holes, a parasitic capacitance between a wiring layer and a neighboring wiring is increased even if the wiring layers are buried in the via holes, whereupon a desired characteristic cannot be achieved.

### SUMMARY OF THE INVENTION

Therefore, an object of the present invention is to provide a semiconductor device in which a parasitic capacitance between neighboring wirings can be suppressed even if a mask pattern is displaced during the forming of via holes.

In one aspect, the present invention provides a semiconductor device comprising a first insulating film having a plurality of wiring trenches formed at predetermined intervals in an upper part thereof, the first insulating film having an upper surface, a second insulating film formed on the upper surface of the first insulating film so as to be located between the wiring trenches, the second insulating film having an upper surface, a wiring layer buried in the wiring trenches and formed so that an upper surface thereof is located lower than an upper surface of the second insulating film, and a via plug formed so as to be connected to the upper surface of the wiring layer.

In another aspect, the invention provides a method of manufacturing a semiconductor device comprising forming, on a first insulating film, a second insulating film and etching parts of the first and second insulating films, said parts belonging to the same region, thereby forming a trench, burying a first wiring layer in the trench, causing an upper part of the first wiring layer to retreat below an upper surface of the second insulating film, forming a third insulating film made from a material different from a material of the second insulating material on the wiring layer and the second insulating film, etching the third insulating film with a higher selection ratio of third insulating film to the second insulating film so that a via hole is formed, and burying a via plug in the via hole.

### BRIEF DESCRIPTION OF THE DRAWINGS

Other objects, features and advantages of the present invention will become clear upon reviewing the following description of the embodiment with reference to the accompanying drawings, in which:

FIG. 1 is a schematic longitudinal section of the wiring structure employed in the semiconductor device in accordance with one embodiment of the present invention, the figure being taken along line 1-1 in FIG. 1;

FIG. 2 is a schematic plan view of the wiring structure;

FIG. 3 is a schematic longitudinal section of the wiring structure in a first step of a manufacturing process (No. 1);

FIG. 4 is a schematic longitudinal section of the wiring structure in a second step of the manufacturing process (No. 2);

FIG. 5 is a schematic longitudinal section of the wiring structure in a third step of the manufacturing process (No. 3);

FIG. 6 is a schematic longitudinal section of the wiring structure in a fourth step of the manufacturing process (No. 4);

FIG. 7 is a schematic longitudinal section of the wiring structure in a fifth step of the manufacturing process (No. 5); and

FIG. 8 is a view similar to FIG. 6, showing the case where a second insulating film is supposed not to be formed.

### DETAILED DESCRIPTION OF THE INVENTION

One embodiment of the present invention will be described with reference to the accompanying drawings. In the embodiment, the invention is applied to a wiring structure in a memory cell region of a dynamic random access memory (DRAM).

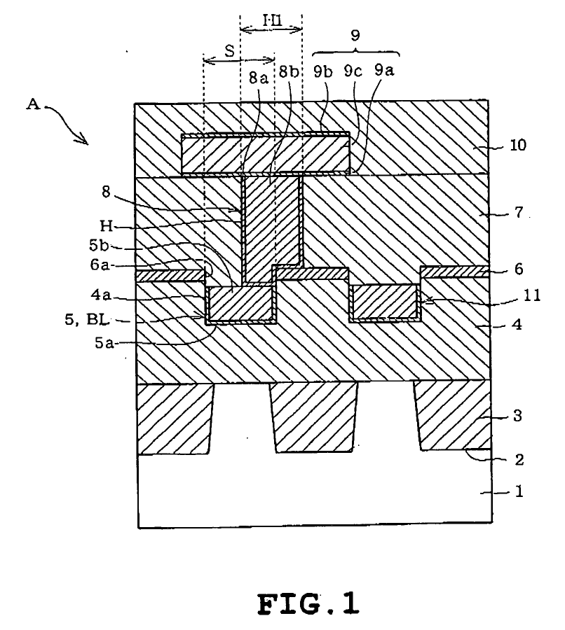

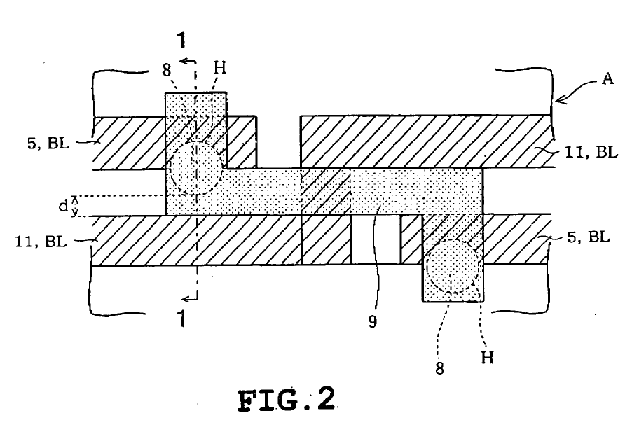

FIG. 2 is a schematic plan view showing a part of the memory cell region of the DRAM. FIG. 1 is a longitudinal side section taken along line 1-1 in FIG. 2. Referring to FIG. 2, reference symbol “BL” designates a bit line. There is a case where the memory cell region of the DRAM A is composed into a structure in which the bit lines BL three-dimensionally intersect so that noise applied to the bit lines BL is reduced as shown in FIG. 2. In the following description, the structure of the embodiment will be described with the invention being applied to the above case.

For example, a switching transistor and a trench capacitor structure are formed at a lower layer side of the bit line BL, whereby a DRAM cell is composed, although none of these elements are shown.

Referring now to FIG. 1, a trench 2 is formed in an upper part of a silicon semiconductor substrate 1. An element isolation insulating film 3 is buried in the trench 2. The element isolation insulating film 3 has an upper surface co-planar with an upper surface of the substrate 1. The element isolation insulating film 3 is comprised of a tetraethyl orthosilicate (TEOS) film or a silicon oxide film.

A silicon oxide film 4 serving as a first insulating film is formed on the substrate 1 and the insulating film 3. A plurality of trenches 4a are formed in an upper part of the silicon oxide film 4. An upper surface of the silicon oxide film 4 except for a formation region of each trench 4 is formed into a flat shape. A first wiring layer 5 (a lower layer wiring and a bit line) is buried in each trench 4a. The first wiring layer 5 includes a barrier metal layer 5a isotropically formed on an inner surface of each trench 4a and a conductive layer 5b buried inside the barrier metal layer 5a. The conductive layer 5b has a flat upper surface. The barrier metal layer 5a is made from Ti and/or TiN, whereas the conductive layer 5b is made from tungsten, for example. The wiring layer 5 is formed so that an upper surface thereof retreats downward relative to the upper surface of the silicon oxide film 4. The upper surface of the wiring layer 5 is formed into a flat shape. The upper surface of the wiring layer 5 may be located upper than the upper surface of the silicon oxide film 4.

Silicon nitride films 6 serving as second insulating films are formed on a region other than the formation region S. Each silicon nitride film 6 is also formed with a trench 6a in the same region as the formation region S of each trench 4. Each silicon film 6 has a film thickness of about 35 nm. Each wiring layer 5 has an upper surface located lower than the upper surface of each silicon nitride film 6, as shown in FIG. 1. Furthermore, an interlayer insulating film 7 serving as a third insulating film is formed on the wiring layers 5 and the silicon nitride films 6. The interlayer insulating film 7 is formed with a via hole H in which a via plug 8 is buried. The via plug 8 is comprised of a barrier metal layer 8a which is formed on an inner surface of the via hole H so as to have a substantially uniform film thickness and a wiring layer 8b buried inside the barrier metal layer 8a.

FIGS. 1 and 2 show a case where a position gap of the formation region H1 has occurred when the via hole H is formed by forming a resist mask pattern on the interlayer insulating film 7 and etching the film 7. More specifically, a formation region H1 for the via hole H and the via plug 8 is displaced rightward as shown in FIG. 1. Furthermore, the formation region H1 is displaced downward as shown in FIG. 2. As a result, the via plug 8 is partially displaced out of the wiring layer 5.

A distance d (see FIG. 2) between the via plug 8 and the neighboring wiring layer 11 (a conductive layer and corresponding to the bit line) is short as an amount of displacement of the via plug 8 becomes larger, as shown in FIG. 2. However, the silicon nitride film 6 is formed on the silicon oxide film 4 and the upper surface of the silicon nitride film 6 is located upper than the upper surface of the wiring layer 5, as shown in FIG. 1. Accordingly, a part of the via plug 8 is placed on the silicon nitride film 6. In other words, the via plug 8 is formed so as to step over the upper surfaces of the wiring layer 5 and the silicon nitride film 6. Consequently, a distance between the wiring layer 11 and the via plug 8 can be rendered longer than in the conventional arrangement even it the via plug 8 is formed so as to be located nearer to the neighboring wiring layer 11 (bit line BL) than designed, by an adverse influence of position gap of the resist mask. As a result, a parasitic capacitance and leak current between the neighboring bit lines BL can be restrained or reduced.

The silicon oxide film 7 and the via plug 8 are formed so that the respective upper surfaces are co-planar as shown in FIG. 1. Furthermore, a wiring layer 9 (second wiring layer and upper layer wiring) is formed so as to be connected to the via plug 8 electrically and structurally. The wiring layer 9 is formed in a bit-line formation region so as to be located on an upper surface of the interlayer insulating film 7. The wiring layer 9 is comprised of a lower layer barrier metal 9a, an upper layer barrier metal 9b and a conductive layer 9c interposed between the barrier metals 9a and 9b. An interlayer insulating film 10 is deposited on the silicon oxide film 7 so as to cover an upper surface and sides of the wiring layer 9.

The wiring layer 5 (the bit line BL) has such a wiring structure as to be electrically conductive horizontally. Furthermore, the via plug 8 has such a wiring structure as to be electrically conductive to the surface of the silicon substrate 1 (the surface of the wiring layer 5) substantially vertically and upward. The wiring layer 9 is provided over the via plug 8 and has such a wiring structure as to be electrically conductive horizontally.

It has conventionally been assumed that occurrence of position gap of the mask pattern would cause a part of the bottom of the via hole H to protrude from over the wiring layer 5 horizontally or that an increase in the diameter of the via hole H or the like would cause a part of the bottom of the via hole H to protrude from over the wiring layer 5 horizontally. For these reasons, the wiring layer 5 is provided with a margin region preventing the bottom of the via hole H from protruding from over the wiring layer 5.

However, with recent improvement in the degree of integrity in the semiconductor devices, an interwiring pitch is reduced and accordingly, the provision of the margin region becomes a factor of increase in a chip area. Thus, the provision of the margin region is not preferred. Additionally, in the case of a semiconductor device including a large number of repeated patterns such as the memory cell region of the DRAM A, the provision of a margin region in each wiring layer also results in increase in a chip area.

According to the above-described embodiment, the silicon nitride film 6 is formed in contact with the formation region S so as to be located upper than the upper surface of the wiring layer 5. The via plug 8 would be formed so as to step over the upper surfaces of the wiring layer 5 and the silicon nitride film 6 if occurrence of position gap of the mask pattern shifts the formation region H1 for the silicon nitride film 6 from a desired position. Even in this case, however, the distance between the via plug 8 buried in the via hole H and the wiring layer 11 can be held long. Consequently, a parasitic capacitance can be suppressed or reduced. Furthermore, an area required for forming a semiconductor chip can be suppressed.

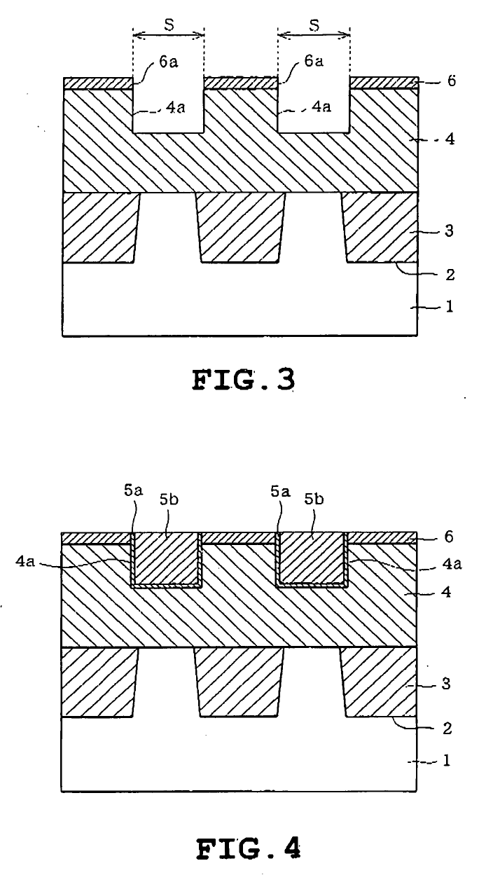

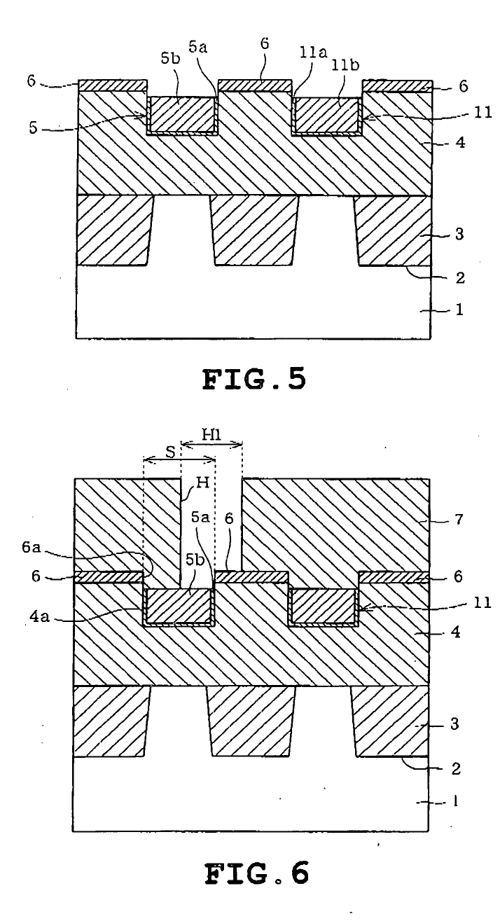

A method of manufacturing the wiring layer 5 by the use of a damascene process will be described with further reference to FIGS. 3 to 8 as well as FIGS. 1 and 2. On condition that the manufacturing method in accordance with the invention can be realized, one or more of the steps which will be described later may be eliminated and/or one or more ordinary steps may be added.

A forming process of the structure as shown in FIG. 3 will be described. A plurality of trenches 2 are formed in an upper part of the silicon substrate 1. The element isolation films 3 are buried in the respective trenches 2, and the upper surface of the substrate 1 will be flattened. Then, the silicon oxide film 4 is formed on the silicon substrate 1 and the element isolation film 3 by the chemical vapor deposition (CVD) process or the like. Subsequently, the silicon nitride film 6 is formed on the silicon oxide film 4 so as to have a film thickness of about 35 nm. The silicon nitride film 6 functions as an etching stopper film when the silicon oxide film is etched so that the trenches 4a are formed. Subsequently, resist (not shown) is applied to the silicon oxide film 4 and then patterned. Thereafter, parts of the silicon nitride film 6 corresponding to a plurality of formation regions S of the conductive layer 5 removed so that a plurality of trenches 6a are formed, and an upper part of the silicon oxide film 4 is removed so that a plurality of trenches 4a are formed. Thus, the structure as shown in FIG. 4 is configured.

Subsequently, as shown in FIG. 4, the barrier metal layers 5a are isotropically formed in the trenches 4a respectively, and the conductive layers 5b are buried inside the barrier metals 5a. The barrier metal layers 5a and the conductive layers 6 are flattened, for example, by the CMP process so that the barrier metal layers 5a and the conductive layers 5b are co-planar with the upper surface of the silicon nitride film 6.

Subsequently, for example, the upper parts of the barrier metal layers 5a and the conductive layers 5b are wet-etched by a mixture of diluted sulfuric acid and hydrogen peroxide water and selectively removed, thereby causing the barrier metal layers 5a and the conductive layers 5b to retreat. An amount of retreat of the wiring layer 5 in this case depends upon a designed value of wiring resistance of the wiring layer 5. Any other etching method that can remove the upper part of the wiring layer 5 may be used. After the etching process, the upper part of the wiring layer 5 is located lower than the upper surface of the silicon nitride film 6.

Subsequently, the interlayer insulating film 7 is deposited on the wiring layer 5 and the silicon nitride film 6 so that the via hole H is formed in the interlayer insulating film 7, as shown in FIG. 6. An anisotropic etching process is carried out for the interlayer insulating film 7 with a higher selection ratio of the interlayer insulating film 7 to the silicon nitride film 6 so that the via hole H is formed. In this case, it is desirable that a formation region of the via hole H should correspond to the formation region of the wiring layer 5. However, it has become difficult to cause the region S to correspond to the region H1 as the result of the improvement in the degree of integration. As a result, the formation region H1 of the via hole H is sometimes shifts from the formation region S of the wiring layer 5. However, since the silicon nitride film 6 functions as an etching stopper film, the interlayer insulating film 7 is just removed in the direction of the depth (downward) in the formation region of the silicon nitride film within the via hole formation region to such an extent that the upper surface of the silicon nitride film 6 is reached. However, the etching process is carried out in the other formation region H1 so that the upper surface of the wiring layer 5 is reached.

In this case, if no silicon nitride film 6 should be formed in the formation region H1 of the via hole H, the etching process would be difficult with a higher selection ratio of the interlayer insulating film 7 to the interlayer insulating film 7 and the silicon oxide film 4. Accordingly, as shown in FIG. 8, the silicon oxide film 4 is etched downward from the upper surface of the wiring layer 5. A trench 7a is formed in the interlayer insulating film 7, and a trench 4a is formed in the silicon oxide film 4.

Subsequently, when the via plug is buried in the trench 4b formed by removing the upper part of the silicon oxide film 4, a distance between the via plug and the conductive layer 11 near to the via plug is shortened such that the parasitic capacitance is increased. In view of this problem, in the embodiment, the etching process is carried out with a higher selection ratio of the interlayer insulating film 7 to the silicon oxide film 4. Consequently, the silicon oxide film 4 formed on the side of the wiring layer 5 can be prevented from being removed.

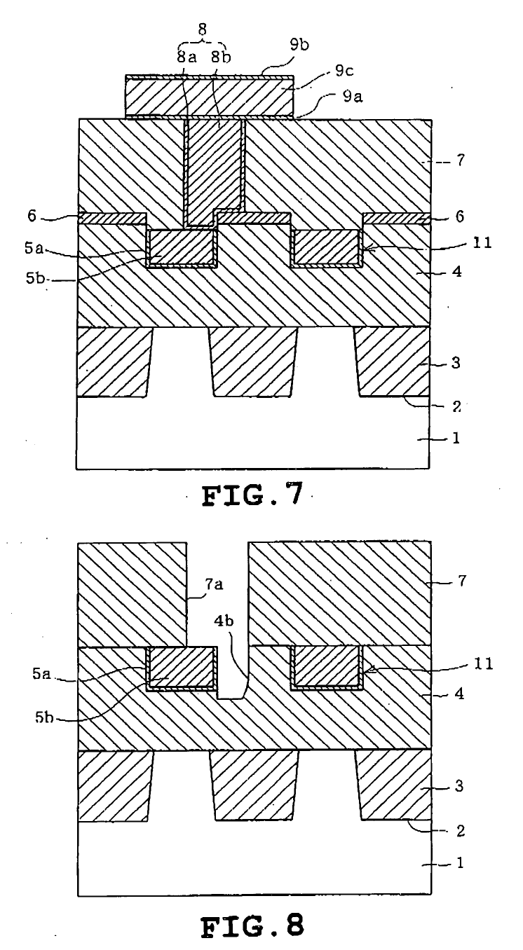

Next, the barrier metal film 8a is formed in the via hole H by the sputtering process or the like as shown in FIG. 7. The wiring layer 8b is buried in the barrier metal film 8a by the CVD process so that the via plug 8 is formed. Thereafter, the upper surface of the interlayer insulating film 7 is flattened by the CMP process or the like. A lower barrier metal layer 9a, a conductive layer 9c and an upper barrier metal 9b are sequentially deposited and patterned into a desired shape by the lithography technique. Each of the lower and upper barrier metals 9a and 9c is comprised of a Ti/TiN laminated film. The conductive layer 9c is made from aluminum or the like. Subsequently, when the interlayer insulating film 10 such as a silicon oxide film is deposited, the structure as shown in FIG. 1 is obtained.

According to the above-described manufacturing method, the silicon oxide film 4 and the silicon nitride film 6 in the region S are etched so that a plurality of trenches 4a are formed. The wiring layers 5 are buried in the trenches 4a. An upper part of the wiring layer 5 is caused to retreat so as to be located lower than the upper surface of the silicon nitride film 6. The silicon oxide film 7 is formed on the wiring layer 5 and the silicon nitride film 6. The silicon oxide film 7 is etched with a higher selection ratio of the silicon oxide film 7 to the silicon nitride film 6 and the wiring layer 5 so that the via hole H is formed. The via plug 8 is buried in the via hole H. Accordingly, even if alignment shift should shift the formation region H1 of the via hole H from the formation region S of the wiring layer 5, the etching process would stop on the upper surface of the silicon nitride film 6. Consequently, the distance between the via plug 8 and the neighboring wiring layer 11 can be held longer, whereby the parasitic capacitance can be suppressed or reduced.

The invention should not be limited to the foregoing embodiment. The embodiment may be modified or expanded as follows. Although the invention is applied to the wiring structure of the memory cell region of the DRAM in the foregoing embodiment, the invention may be applied to other semiconductor devices. Although the silicon oxide film 4 serves as the first insulating film in the foregoing embodiment, the aforesaid effect is more conspicuous when the film 4 is made from the same material as the interlayer insulating film 7. In the foregoing embodiment, the silicon nitride film 6 serves as the second insulating film and the silicon oxide film serves as the third insulating film. Each insulating film may be made from any material on condition that the second and third insulating films are made from different materials and the third insulating film has a higher selection ratio to the second insulating film.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor device comprising:
a first insulating film having a plurality of wiring trenches formed at predetermined intervals in an upper part thereof, the first insulating film having an upper surface;
a second insulating film formed on the upper surface of the first insulating film so as to be located between the wiring trenches, the second insulating film having an upper surface;
a wiring layer buried in the wiring trenches and formed so that an upper surface thereof is located lower than an upper surface of the second insulating film; and
a via plug formed so as to be connected to the upper surface of the wiring layer.

2. The semiconductor device according to claim 1, wherein the first insulating film is formed by a silicon oxide film and the second insulating film is formed by a silicon nitride film.

3. A method of manufacturing a semiconductor device comprising:
forming, on a first insulating film, a second insulating film and etching parts of the first and second insulating films, said parts belonging to the same region, thereby forming a trench;
burying a wiring layer in the trench;
causing an upper part of the wiring layer to retreat below an upper surface of the second insulating film;
forming a third insulating film made from a material different from a material of the second insulating material on the wiring layer and the second insulating film;
etching the third insulating film with a higher selection ratio of the third insulating film to the second insulating film so that a via hole is formed; and
burying a via plug in the via hole.

4. The method according to claim 3, wherein a silicon nitride film is formed as the second insulating film and a silicon oxide film is formed as the third insulating film.
